(19) United States
(12) Patent Application Publication
(10) Pub. No.: US 2024/0023271 A1
(43) Pub. Date: Jan. 18, 2024

(54) NOISE ATTENUATION FAN

(71) Applicant: Dell Products L.P., Round Rock, TX (US)

(72) Inventor: Qinghong He, Austin, TX (US)

(21) Appl. No.: 17/812,847

(22) Filed: Jul. 15, 2022

(51) Int. Cl. H05K 7/20; G06F 1/20

(52) U.S. Cl. CPC H05K 7/20172; G06F 1/20

(57) ABSTRACT

In one or more embodiments, one or more systems and/or one or more processes comprises a fan with a plurality of blades, with each blade extending radially outward from the central body to define a blade length, each blade having two surfaces, wherein each surface of the two surfaces has a blade surface profile, wherein at least one surface of the two surfaces comprises a plurality of turbulators that define a portion of the blade surface profile, and each turbulator of the plurality of turbulators extends at least a portion of a width of the blade. The turbulators may delay airflow separation from the blade to increase the laminar flow region and reduce noise.

### BACKGROUND

### Field of the Disclosure

This disclosure relates generally to fans and other air movers in information handling systems and more particularly to noise attenuation fans.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

In one or more embodiments, one or more systems and/or one or more processes may be generally directed to a noise attenuation fan comprising a plurality of blades coupled to the central body, wherein each blade of the plurality of blades extends radially outward from the central body to define a blade length, each blade has two surfaces, wherein each surface of the two surfaces has a blade surface profile, wherein at least one surface of the two surfaces comprises a plurality of turbulators that define a portion of the blade surface profile, and each turbulator of the plurality of turbulators extends at least a portion of the blade surface.

In some embodiments, each turbulator of the plurality of turbulators is formed with a pitch relative to a surface of the two surfaces. In some embodiments, the pitch is based on a radial distance of the turbulator from the central body. In some embodiments, the plurality of turbulators defines a blade surface profile with a graduated pitch, wherein each turbulator has a pitch greater than a radially-inward turbulator. In some embodiments, each turbulator is separated from an adjacent turbulator by a distance based on the radial distance from the central body. In some embodiments, the pitch of each turbulator is substantially constant over the blade length. In some embodiments, a first surface of the two surfaces comprises a first set of the plurality of turbulators and a second surface of the two surfaces comprises a second set of the plurality of turbulators. In some embodiments, each blade of the plurality of blades is formed with a plurality of curves, wherein the plurality of curves defines the blade surface profile for each surface of the two surfaces. In some embodiments, the fan is configured to generate airflow in a radial direction.

In one or more embodiments, one or more systems and/or one or more processes may be generally directed to a cooling system for an information handling system, the cooling system comprising a motor with an output shaft defining an axis, a controller operable to control a rotational speed of the output shaft and a noise attenuation fan comprising a central body coupled to the output shaft and rotatable about the axis and a plurality of blades coupled to the central body for generating an airflow, wherein each blade of the plurality of blades extends radially outward from the central body to define a blade length, each blade has two surfaces, wherein each surface of the two surfaces has a blade surface profile, wherein at least one surface of the two surfaces comprises a plurality of turbulators that define a portion of the blade surface profile, and each turbulator of the plurality of turbulators extends at least a portion of the blade surface.

### BRIEF DESCRIPTION OF THE DRAWINGS

For a more complete understanding of the present disclosure and its features/advantages, reference is now made to the following description, taken in conjunction with the accompanying drawings, which are not drawn to scale, and in which:

FIG. 1 depicts a perspective view of an example fan;

FIG. 2 depicts an image of a simulated air flow generated by the example fan of FIG. 1;

FIG. 3 depicts a perspective view of one embodiment of a noise attenuation fan;

FIG. 4 depicts an image of a simulated air flow generated by the embodiment of a noise attenuation fan of FIG. 3;

FIG. 5 depicts a top view of a fan blade with a substantially constant thickness formed to comprise a plurality of turbulators according to one embodiment of a noise attenuation fan;

FIG. 6 depicts a top view of a fan blade formed with a plurality of curved turbulators on one surface according to one embodiment of a noise attenuation fan;

FIG. 7 depicts a top view of a fan blade formed with a plurality of angled turbulators on one surface according to one embodiment of a noise attenuation fan;

FIG. 8 depicts a perspective view of one embodiment of a noise attenuation fan in which each fan blade is formed with a plurality of turbulators on only a portion of the width of each surface; and

FIG. 9 depicts a perspective view of one embodiment of a noise attenuation fan capable of generating airflow in an axial direction, in which each fan blade is formed with a plurality of turbulators.

### DETAILED DESCRIPTION

In the following description, details are set forth by way of example to facilitate discussion of the disclosed subject matter. It should be apparent to a person of ordinary skill in the field, however, that the disclosed embodiments are examples and not exhaustive of all possible embodiments.

As used herein, a reference numeral refers to a class or type of entity, and any letter following such reference numeral refers to a specific instance of a particular entity of that class or type. Thus, for example, a surface referenced by ‘14A’ may refer to a particular surface, and the reference ‘14’ may refer to a collection of surfaces belonging to that particular class/type or any one instance of that class/type in general.

An information handling system (IHS) may include a hardware resource or an aggregate of hardware resources operable to compute, classify, process, transmit, receive, retrieve, originate, switch, store, display, manifest, detect, record, reproduce, handle, and/or utilize various forms of information, intelligence, or data for business, scientific, control, entertainment, or other purposes, according to one or more embodiments. For example, an IHS may be a personal computer, a desktop computer system, a laptop computer system, a server computer system, a mobile device, a tablet computing device, a personal digital assistant (PDA), a consumer electronic device, an electronic music player, an electronic camera, an electronic video player, a wireless access point, a network storage device, or another suitable device and may vary in size, shape, performance, functionality, and price. In one or more embodiments, a portable IHS may include or have a form factor of that of or similar to one or more of a laptop, a notebook, a telephone, a tablet, and a PDA, among others. For example, a portable IHS may be readily carried and/or transported by a user (e.g., a person). In one or more embodiments, components of an IHS may include one or more storage devices, one or more communications ports for communicating with external devices as well as various input and output (I/O) devices, such as a keyboard, a mouse, and a video display, among others. In one or more embodiments, IHS may include one or more buses operable to transmit communication between or among two or more hardware components. In one example, a bus of an IHS may include one or more of a memory bus, a peripheral bus, and a local bus, among others. In another example, a bus of an IHS may include one or more of a Micro Channel Architecture (MCA) bus, an Industry Standard Architecture (ISA) bus, an Enhanced ISA (EISA) bus, a Peripheral Component Interconnect (PCI) bus, HyperTransport (HT) bus, an inter-integrated circuit (I²C) bus, a serial peripheral interface (SPI) bus, a low pin count (LPC) bus, an enhanced serial peripheral interface (eSPI) bus, a universal serial bus (USB), a system management bus (SMBus), and a Video Electronics Standards Association (VESA) local bus, among others.

In one or more embodiments, an IHS may include firmware that controls and/or communicates with one or more hard drives, network circuitry, one or more memory devices, one or more I/O devices, and/or one or more other peripheral devices. For example, firmware may include software embedded in an IHS component utilized to perform tasks. In one or more embodiments, firmware may be stored in non-volatile memory, such as storage that does not lose stored data upon loss of power. In one example, firmware associated with an IHS component may be stored in non-volatile memory that is accessible to one or more IHS components. In another example, firmware associated with an IHS component may be stored in non-volatile memory that may be dedicated to and includes part of that component. For instance, an embedded controller may include firmware that may be stored via non-volatile memory that may be dedicated to and includes part of the embedded controller.

An IHS may include a processor, a volatile memory medium, non-volatile memory media, an I/O subsystem, and a network interface. Volatile memory medium, non-volatile memory media, I/O subsystem, and network interface may be communicatively coupled to processor. In one or more embodiments, one or more of volatile memory medium, non-volatile memory media, I/O subsystem, and network interface may be communicatively coupled to processor via one or more buses, one or more switches, and/or one or more root complexes, among others. In one example, one or more of a volatile memory medium, non-volatile memory media, an I/O subsystem, and a network interface may be communicatively coupled to the processor via one or more PCI-Express (PCIe) root complexes. In another example, one or more of an I/O subsystem and a network interface may be communicatively coupled to processor via one or more PCIe switches.

In one or more embodiments, the term “memory medium” may mean a “storage device”, a “memory”, a “memory device”, a “tangible computer readable storage medium”, and/or a “computer-readable medium”. For example, computer-readable media may include, without limitation, storage media such as a direct access storage device (e.g., a hard disk drive, a floppy disk, etc.), a sequential access storage device (e.g., a tape disk drive), a compact disk (CD), a CD-ROM, a digital versatile disc (DVD), a random access memory (RAM), a read-only memory (ROM), a one-time programmable (OTP) memory, an electrically erasable programmable read-only memory (EEPROM), and/or a flash memory, a solid state drive (SSD), or any combination of the foregoing, among others.

In one or more embodiments, one or more protocols may be utilized in transferring data to and/or from a memory medium. For example, the one or more protocols may include one or more of small computer system interface (SCSI), Serial Attached SCSI (SAS) or another transport that operates with the SCSI protocol, advanced technology attachment (ATA), serial ATA (SATA), a USB interface, an Institute of Electrical and Electronics Engineers (IEEE) 1394 interface, a Thunderbolt interface, an advanced technology attachment packet interface (ATAPI), serial storage architecture (SSA), integrated drive electronics (IDE), or any combination thereof, among others.

A volatile memory medium may include volatile storage such as, for example, RAM, DRAM (dynamic RAM), EDO RAM (extended data out RAM), SRAM (static RAM), etc. One or more of non-volatile memory media may include nonvolatile storage such as, for example, a read only memory (ROM), a programmable ROM (PROM), an erasable PROM (EPROM), an electrically erasable PROM, NVRAM (non-volatile RAM), ferroelectric RAM (FRAM), a magnetic medium (e.g., a hard drive, a floppy disk, a magnetic tape, etc.), optical storage (e.g., a CD, a DVD, a BLU-RAY disc, etc.), flash memory, a SSD, etc. In one or more embodiments, a memory medium can include one or more volatile storages and/or one or more nonvolatile storages.

In one or more embodiments, a network interface may be utilized in communicating with one or more networks and/or one or more other information handling systems. In one example, network interface may enable an IHS to communicate via a network utilizing a suitable transmission protocol and/or standard. In a second example, a network interface may be coupled to a wired network. In a third example, a network interface may be coupled to an optical network. In another example, a network interface may be coupled to a wireless network. In one instance, the wireless network may include a cellular telephone network. In a second instance, the wireless network may include a satellite telephone network. In another instance, the wireless network may include a wireless Ethernet network (e.g., a Wi-Fi network, an IEEE 802.11 network, etc.).

In one or more embodiments, a network interface may be communicatively coupled via a network to a network storage resource. For example, the network may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, an Internet or another appropriate architecture or system that facilitates the communication of signals, data and/or messages (generally referred to as data). For instance, the network may transmit data utilizing a desired storage and/or communication protocol, including one or more of Fibre Channel, Frame Relay, Asynchronous Transfer Mode (ATM), Internet protocol (IP), other packet-based protocol, Internet SCSI (iSCSI), or any combination thereof, among others.

In one or more embodiments, a processor may execute processor instructions in implementing at least a portion of one or more systems, at least a portion of one or more flowcharts, at least a portion of one or more methods, and/or at least a portion of one or more processes. In one example, a processor may execute processor instructions from one or more memory media in implementing at least a portion of one or more systems, at least a portion of one or more flowcharts, at least a portion of one or more methods, and/or at least a portion of one or more processes. In another example, a processor may execute processor instructions via a network interface in implementing at least a portion of one or more systems, at least a portion of one or more flowcharts, at least a portion of one or more methods, and/or at least a portion of one or more processes.

In one or more embodiments, a processor may include one or more of a system, a device, and an apparatus operable to interpret and/or execute program instructions and/or process data, among others, and may include one or more of a microprocessor, a microcontroller, a digital signal processor (DSP), an application specific integrated circuit (ASIC), and another digital or analog circuitry configured to interpret and/or execute program instructions and/or process data, among others. In one example, a processor may interpret and/or execute program instructions and/or process data stored locally (e.g., via memory media and/or another component of an IHS). In another example, a processor may interpret and/or execute program instructions and/or process data stored remotely (e.g., via a network storage resource).

In one or more embodiments, an I/O subsystem may represent a variety of communication interfaces, graphics interfaces, video interfaces, user input interfaces, and/or peripheral interfaces, among others. For example, an I/O subsystem may include one or more of a touch panel and a display adapter, among others. For instance, a touch panel may include circuitry that enables touch functionality in conjunction with a display that is driven by a display adapter.

A non-volatile memory medium may include an operating system (OS) and applications (APPs). In one or more embodiments, one or more of an OS and APPs may include processor instructions executable by a processor. In one example, a processor may execute processor instructions of one or more of OS and APPs via a non-volatile memory medium. In another example, one or more portions of the processor instructions of one or more of an OS and APPs may be transferred to a volatile memory medium and a processor may execute the one or more portions of the processor instructions.

Non-volatile memory medium may include information handling system firmware (IHSFW). In one or more embodiments, IHSFW may include processor instructions executable by a processor. For example, IHSFW may include one or more structures and/or one or more functionalities of and/or compliant with one or more of a basic input/output system (BIOS), an Extensible Firmware Interface (EFI), a Unified Extensible Firmware Interface (UEFI), and an Advanced Configuration and Power Interface (ACPI), among others. In one instance, a processor may execute processor instructions of IHSFW via non-volatile memory medium. In another instance, one or more portions of the processor instructions of IHSFW may be transferred to volatile memory medium, and processor may execute the one or more portions of the processor instructions of IHSFW via volatile memory medium.

An information handling system as described above may generate heat during operation. A common approach to removing heat is to operate a fan to generate an airflow.

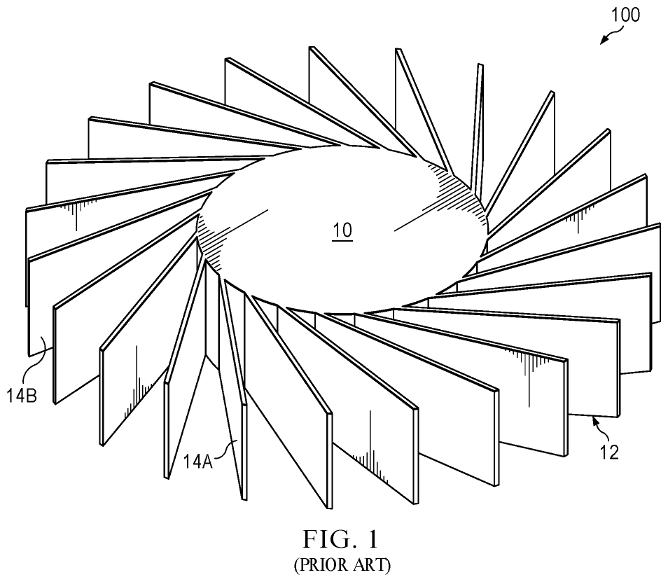

Turning to the drawings, FIG. 1 depicts a perspective view of an example fan 100 having a central body 10 rotatable about an axis, with a plurality of blades 12 coupled to the central body 10. Each blade 12 may be generally straight and have a generally constant thickness and comprise substantially smooth, linear surfaces 14A and 14B. Fan 100 as depicted in FIG. 1 may be rotated clockwise to generate a radial airflow, wherein surface 14A may also be referred to as a leading surface and surface 14B may also be referred to as a trailing surface.

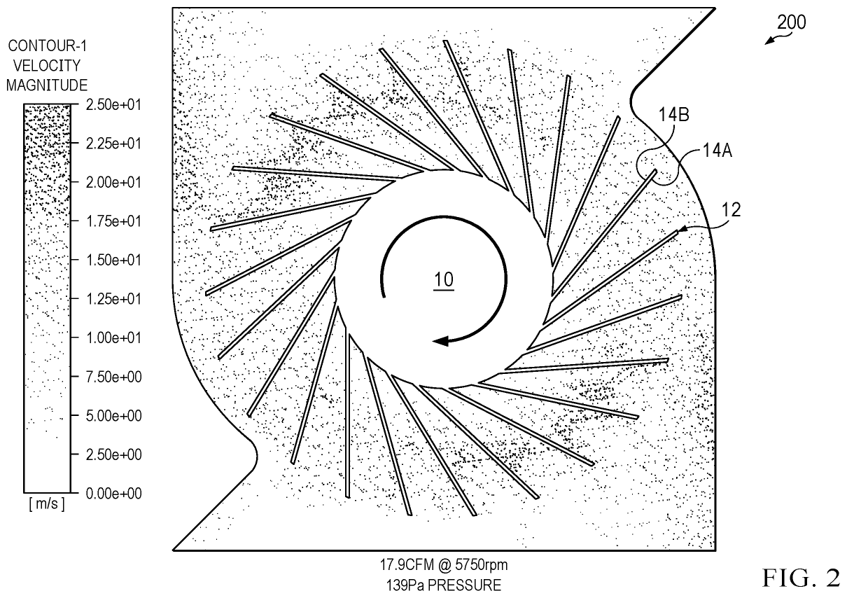

FIG. 2 depicts an image 200 of a simulated airflow velocity profile for fan 100. As depicted in FIG. 2, rotation of fan 100 at 5750 revolutions per minute (RPM) may generate a profile with an airflow of 17.9 cubic feet per minute (CFM) at 139 Pa of pressure. In generating this airflow, fan 100 may produce 3.4 E-7 W/m\hat{ }3 of acoustic energy, resulting in 51.4 dB of blade acoustics.

Embodiments disclosed herein may include a fan and a cooling system capable of generating airflows at lower fan speeds and/or resulting in lower acoustic energy and lower noise. Embodiments disclosed herein may include fans with a plurality of blades, wherein each blade may have at least a portion of at least one surface comprising a plurality of turbulators associated with a blade surface profile for delaying air separation from the blade. At least a portion of each blade has turbulators formed such that the blade surface profile is non-linear, which may cause local recirculated airflow that delays air separation from the blade. A delay in airflow separation may extend the laminar region to reduce turbulence near the blade, which may reduce fan noise associated with aeroacoustics.

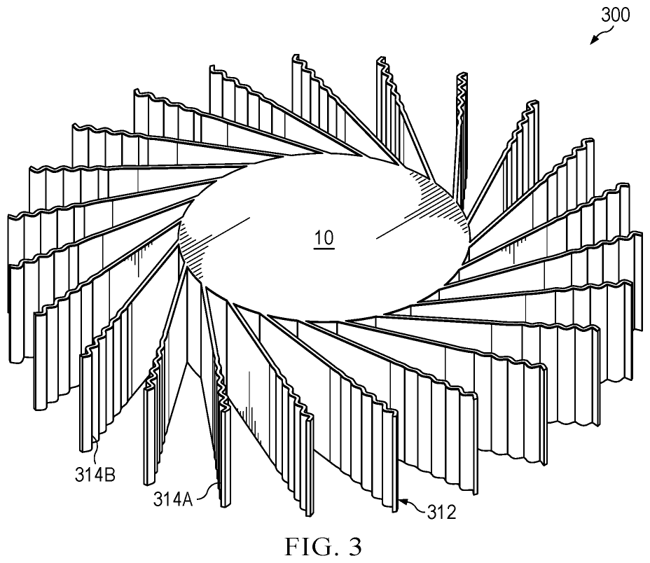

FIG. 3 depicts one embodiment of fan 300 capable of generating a radial airflow. Fan 300 comprises central body 10 rotatable about an axis with a plurality of blades 312 coupled to central body 10. Each blade 312 may have a plurality of turbulators 316 such that a blade surface profile of one or more of surfaces 314A and 314B is non-linear over at least a portion of blade 312, discussed in greater detail below. Each turbulator 316 may be shaped to reduce turbulence in the layer of air next to blade surface 314. A plurality of turbulators 316 may be arranged perpendicular to an airflow generated by fan 300, wherein each turbulator may be formed over at least a portion of the width of each blade 312. As depicted in FIG. 3, in some embodiments, blades 312 may be formed with curves such that the blade surface profiles of surfaces 314 comprise turbulators 316 formed as waves. In some embodiments, blades 312 may be formed with angles or may have some other shape, discussed in greater detail below. In some embodiments, each turbulator 316 may extend a width of a blade 312 or extend only a portion of the width of a blade 312.

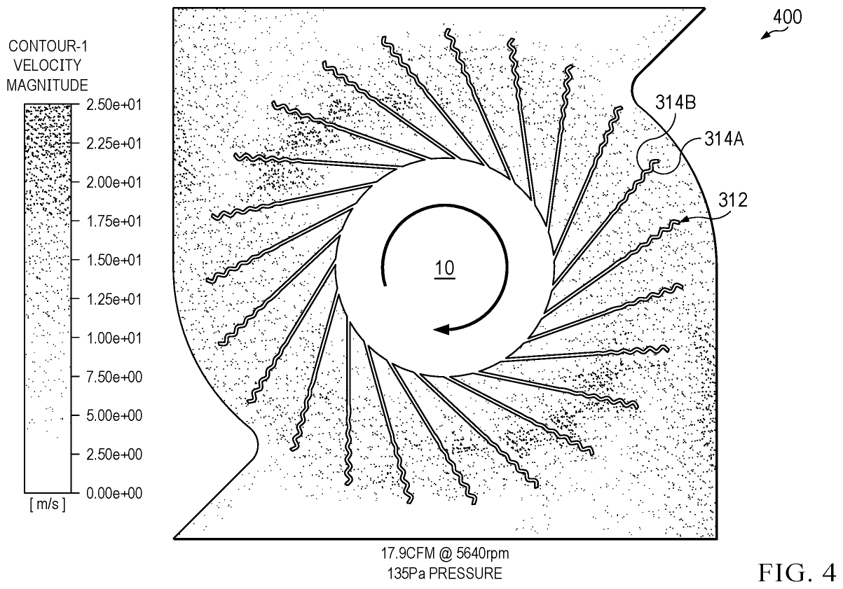

FIG. 4 depicts an image 400 of a simulated airflow velocity profile for fan 300 depicted in FIG. 3. As depicted in FIG. 4, rotation of fan 300 at 5640 revolutions per minute (RPM) may generate the same airflow as fan 100 (i.e., 17.9 CFM) and the profile may appear similar to the simulated profile of fan 100. Thus, fan 300 may be rotated at a slower fan speed but still generate the same airflow volume and have a similar profile. Furthermore, in generating this airflow, fan 300 may produce 2.9 E-7 W/m\hat{ }3 of acoustic energy (approximately 13.5% less acoustic energy than the 3.4 E-7 W/m\hat{ }3 of acoustic energy produced by fan 100), resulting in 48.6 dB of blade acoustics (2.8 dB quieter than fan 100). Thus, fan 300 may generate an airflow at a lower pressure (e.g., 135 Pa instead of 139 Pa) and generate less acoustic energy (e.g., 2.9 E-7 W/m\hat{ }3 instead of 3.4 E-7 W/m\hat{ }3) and be quieter (e.g., 48.6 dB instead of 51.4 dB).

### Blade Surface Profile May Vary

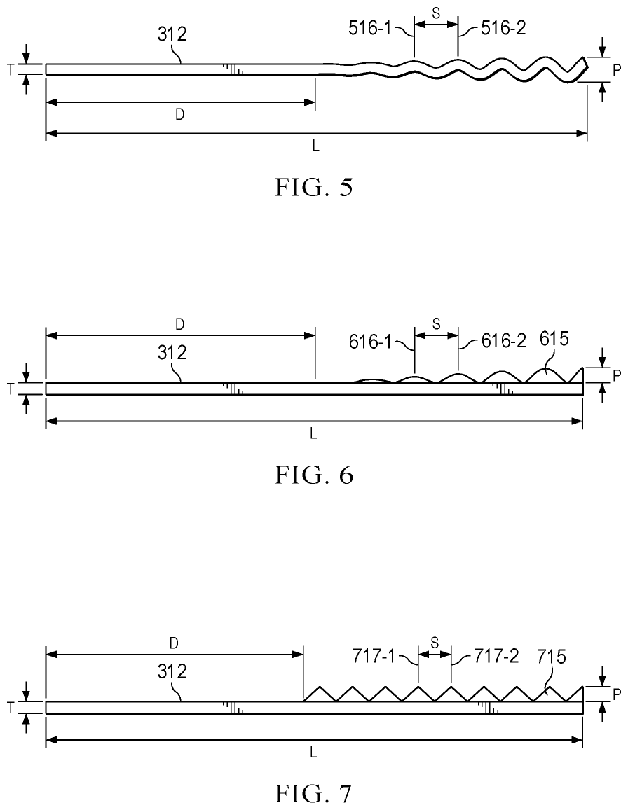

Referring to FIGS. 3 and 5, in some embodiments, blades 312 may be formed with a blade surface profile based on a substantially constant thickness (T) over a length (L) but be formed into a shape such that a blade surface profile of each surface 514 comprises a plurality of turbulators 516 starting a distance D from central body, wherein each turbulator 516 may be formed over a width of a blade 312. A pitch P may be defined for each turbulator 516, wherein the pitch P for turbulators 516 may be defined as the peak of each turbulator 516. In some embodiments, the pitch P of a plurality of turbulators 516 may be constant. In some embodiments, the pitch P of a turbulator 516 of a plurality of turbulators 516 may depend on the radial distance D of each turbulator 516 from central body 10. For example, in some embodiments, the pitch P of turbulator 516-2 may be greater than a pitch P of turbulator 516-1 due to turbulator 516-2 being radially outward of turbulator 516-1. Each turbulator 516 of a plurality of turbulators 516 may be separated by an adjacent turbulator 516 of the plurality of turbulators 516 by a distance S. In some embodiments, the distance S between adjacent turbulators 516 may vary based on a radial distance D from central body 10. In some embodiments, the distance S between adjacent turbulators 516 increases at radially outward distances D.

Referring to FIGS. 3 and 6, blade 312 may be formed with a blade surface profile based on a plurality of curved turbulators 616 arranged over a length (L), wherein a thickness (T) of blade 312 may vary over length L. As depicted in FIG. 6, in some embodiments, material 615 may be added to blade 312 such that a blade surface profile comprises a plurality of turbulators 616 extending a width of each blade 312 but on only one surface 614, wherein surface 614 may be a leading surface or a trailing surface. As depicted in FIG. 6, turbulators 616 may be curved. A curved turbulator 616 may be symmetric, may be defined by a radius, or may have some other curved shape. In some embodiments, material 615 and blade 312 are formed as a single unit. A pitch P may be defined for each turbulator 616, wherein the pitch P for turbulators 616 may be defined as the peak of each turbulator 616. In some embodiments, the pitch P of a plurality of turbulators 616 may be constant. In some embodiments, the pitch P of a turbulator 616 of a plurality of turbulators 616 may depend on the radial distance D of each turbulator 616 from central body 10. For example, in some embodiments, the pitch P of turbulator 616-2 may be greater than a pitch P of turbulator 616-1 due to turbulator 616-2 being radially outward of turbulator 616-1. Each turbulator 616 of a plurality of turbulators 616 may be separated by an adjacent turbulator 616 of the plurality of turbulators 616 by a distance S. In some embodiments, the distance S between adjacent turbulators 616 may vary based on a radial distance D from central body 10. In some embodiments, the distance S between adjacent turbulators 616 increases at radially outward distances D.

Referring to FIG. 7, blade 312 may be formed with a blade surface profile based on a plurality of angled turbulators 716 over a length (L), wherein a thickness (T) of blade 312 may vary over length L. As depicted in FIG. 7, in some embodiments, material 715 may be added to blade 712 such that a blade surface profile comprises a plurality of turbulators 716 extending a width of each blade 312 but on only one surface 714, wherein surface 714 may be a leading surface or a trailing surface. As depicted in FIG. 7, turbulators 616 may be angled. An angled turbulator 716 may be symmetric, may be defined by a slope, or may have some other angled shape. In some embodiments, material 715 and blade 312 are formed as a single unit. A pitch P may be defined for each turbulator 716, wherein the pitch P for turbulators 716 may be defined as the peak of each turbulator 716. In some embodiments, the pitch P of a plurality of turbulators 716 may be constant. In some embodiments, the pitch P of a turbulator 716 of a plurality of turbulators 716 may depend on the radial distance D of each turbulator 716 from central body 10. For example, in some embodiments, the pitch P of turbulator 716-2 may be greater than a pitch P of turbulator 716-1 due to turbulator 716-2 being radially outward of turbulator 716-1. Each turbulator 716 of a plurality of turbulators 716 may be separated by an adjacent turbulator 716 of the plurality of turbulators 716 by a distance S. In some embodiments, the distance S between adjacent turbulators 716 may vary based on a radial distance D from central body 10. In some embodiments, the distance S between adjacent turbulators 716 increases at radially outward distances D.

### Turbulators May be Formed on a Portion of the Width of a Surface

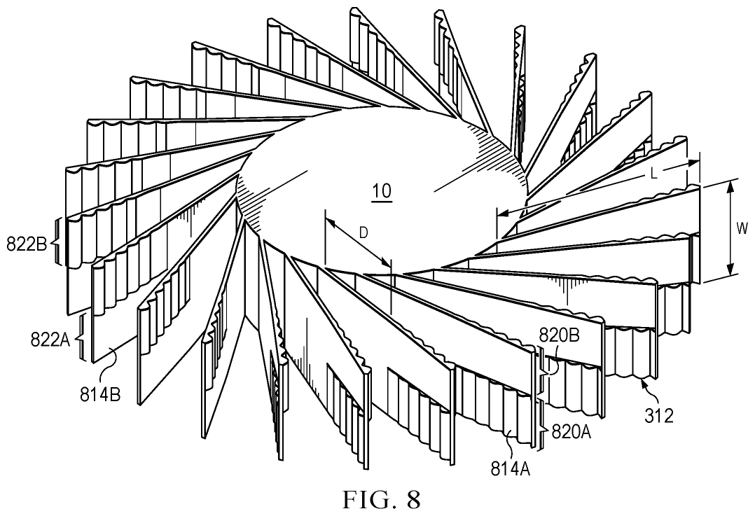

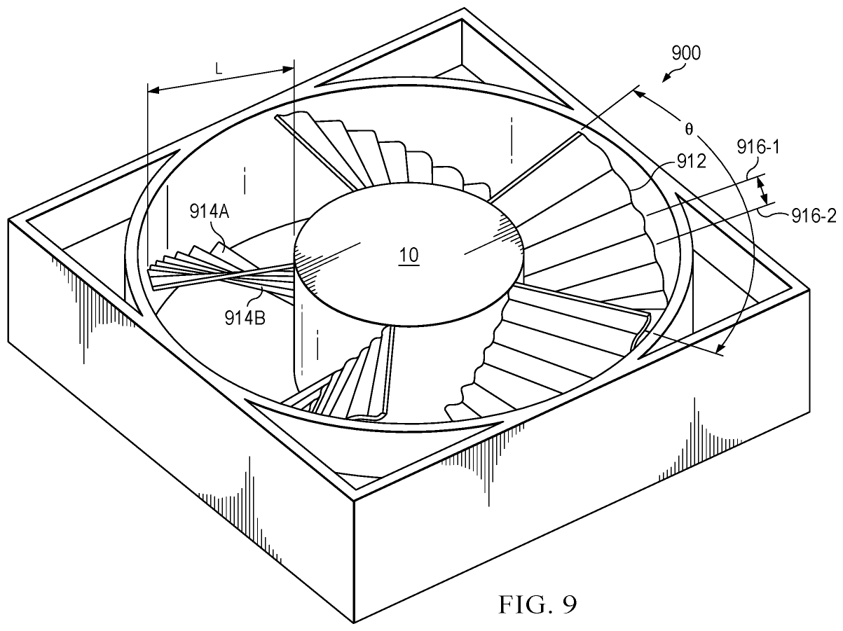

Referring to FIG. 8, in some embodiments a plurality of blades 312 coupled to central body 10 may be formed with a blade surface profile comprising one or more surfaces 814A, 814B of each blade 312 comprising a plurality of turbulators 816 formed on a first portion (e.g., 820A or 822B) of the width, wherein a second portion (e.g., 820B or 822A) of the width of each blade 312 may be substantially linear.

### Fan May be an Axial Flow Fan

Referring to FIG. 9, embodiments may be implemented on fan 900 capable of generating axial airflow. A plurality of blades 912 may be coupled to central body 10. Each blade 912 may have a length (L) and extend an arclength (M) between a leading edge and a trailing edge, and may have a blade surface profile comprising a plurality of turbulators 916. Surfaces 914 may be formed with turbulators 916 that extend the length (L) of each blade 912. Each turbulator 916 may define a pitch (P). In some embodiments, the pitch P of each turbulator 916 of the plurality of turbulators 916 may be constant. In some embodiments, the pitch P of each turbulator 916 of the plurality of turbulators 916 may vary based on an arclength (N) between the leading edge and the turbulator 916. Each turbulator 916 may be separated by an adjacent turbulator 916 by an arclength (O). In some embodiments, the arclength O between adjacent turbulators 916 on blade 312 may vary based on an arclength N between the turbulator 916 and a leading edge of blade 312. In some embodiments, the arclength O between adjacent turbulators 916 increases as the arclength N between the turbulator 916 and a leading edge of blade 312 increases.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A noise attenuation fan comprising:
a central body rotatable about an axis; and
a plurality of blades coupled to the central body, wherein
each blade of the plurality of blades extends radially outward from the central body to define a blade length,
each blade has two surfaces, wherein each surface of the two surfaces has a blade surface profile, wherein at least one surface of the two surfaces comprises a plurality of turbulators that define a portion of the blade surface profile, and
each turbulator of the plurality of turbulators extends at least a portion of a width of the at least one surface.

2. The noise attenuation fan of claim 1, wherein each turbulator of the plurality of turbulators is formed with a pitch relative to the at least one surface of the two surfaces.

3. The noise attenuation fan of claim 2, wherein the pitch is based on a radial distance of the turbulator from the central body.

4. The noise attenuation fan of claim 3, wherein the plurality of turbulators defines the blade surface profile with a graduated pitch, wherein a first turbulator has a first pitch and a second turbulator located radially outward of the first turbulator has a second pitch greater than the first pitch.

5. The noise attenuation fan of claim 4, wherein the second turbulator is separated from the first turbulator by a distance based on the radial distance from the central body to the second turbulator.

6. The noise attenuation fan of claim 1, wherein the pitch of the plurality of turbulators is substantially constant over the blade length.

7. The noise attenuation fan of claim 1, wherein a first surface of the two surfaces comprises a first set of the plurality of turbulators and a second surface of the two surfaces comprises a second set of the plurality of turbulators.

8. The noise attenuation fan of claim 1, wherein each blade of the plurality of blades is formed with a plurality of curves, wherein the plurality of curves defines the blade surface profile for each surface of the two surfaces.

9. The noise attenuation fan of claim 1, wherein the fan is configured to generate airflow in a radial direction.

10. A cooling system for an information handling system, the cooling system comprising:
a motor with an output shaft defining an axis;
a controller operable to control a rotational speed of the output shaft; and
a noise attenuation fan comprising:
a central body rotatable about an axis; and
a plurality of blades coupled to the central body, wherein
each blade of the plurality of blades extends radially outward from the central body to define a blade length,
each blade has two surfaces, wherein each surface of the two surfaces has a blade surface profile, wherein at least one surface of the two surfaces comprises a plurality of turbulators that define a portion of the blade surface profile, and
each turbulator of the plurality of turbulators extends at least a portion of a width of the at least one surface.

11. The cooling system of claim 10, wherein each turbulator of the plurality of turbulators is formed with a pitch relative to a surface of the two surfaces.

12. The cooling system of claim 11, wherein the pitch of each turbulator is based on a radial distance of the turbulator from the central body.

13. The cooling system of claim 12, wherein the plurality of turbulators defines a blade surface profile with a graduated pitch, wherein a first turbulator has a first pitch and a second turbulator located radially outward of the first turbulator has a second pitch greater than the first pitch.

14. The cooling system of claim 13, wherein the second turbulator is separated from the first turbulator by a distance based on the radial distance from the central body to the second turbulator.

15. The cooling system of claim 10, wherein the pitch of the plurality of turbulators is substantially constant over the blade length.

16. The cooling system of claim 10, wherein a first surface of the two surfaces comprises a first set of the plurality of turbulators and a second surface of the two surfaces comprises a second set of the plurality of turbulators.

17. The cooling system of claim 10, wherein each blade of the plurality of blades is formed with a plurality of curves, wherein the plurality of curves defines the blade surface profile for each surface of the two surfaces.

18. The cooling system of claim 10, wherein the fan is configured to generate airflow in a radial direction.
